(19) United States
(12) Patent Application Publication
(10) Pub. No.: US 2012/0003841 A1
(43) Pub. Date: Jan. 5, 2012

(54) METHOD OF PRODUCING SEMICONDUCTOR DEVICE

(75) Inventors: Shinichi Chikaki, Kanagawa (JP); Takahiro Nakayama, Ibaraki (JP)

(73) Assignee: ULVAC, INC., Kanagawa (JP)

(21) Appl. No.: 13/256,578

(22) PCT Filed: Mar. 18, 2010
(86) PCT No.: PCT/JP2010/001935

§ 371 Date: Sep. 14, 2011

(30) Foreign Application Priority Data
Mar. 24, 2009 (JP) 2009-072401

(51) Int. Cl. H01L 21/31

(52) U.S. Cl. 438/778; 257/E21.24

(57) ABSTRACT

A method of manufacturing a semiconductor device includes: a step of forming a porous dielectric film on a substrate; a step of disposing the substrate having the porous dielectric film formed thereon inside a chamber; a step of introducing siloxane into the chamber in which the substrate is disposed and heating the substrate to a first temperature; and a step heating the substrate to which the introduced siloxane adheres to a second temperature higher than the first temperature. A pressure inside the chamber is maintained to be equal to or lower than 1 kPa. In the present embodiment, the first temperature is equal to or higher than a temperature at which the pressure inside the chamber is a saturated vapor pressure of the siloxane, and is equal to or lower than a temperature at which a polymerization between the porous dielectric film and the siloxane starts.

### TECHNICAL FIELD

The invention relates to a method of manufacturing a semiconductor device.

### BACKGROUND ART

In recent years, porous dielectric films having a low dielectric constant have been used in a multi-layer interconnect structure of semiconductor integrated circuit devices. Since the porous dielectric films are likely to absorb moisture contained in the air or the like, there is a problem in that the low dielectric properties and insulating properties are impaired. In response to the problems, the surface of the porous dielectric film is modified through a hydrophobic treatment using organosilane compounds. Examples of a technique relating to the modifying treatment of the surface of the porous dielectric film are disclosed in Patent Documents 1 to 4.

In a method disclosed in Patent Document 1, first, the surface is treated with a sol-gel precursor containing surfactant. Subsequently, the sol-gel precursor is cured to form an oxide film having interconnecting pores of uniform diameter. Subsequently, the oxide film is annealed in an inert gas atmosphere or is exposed to an oxidizing environment including reactive oxygen species. In this way, the porous dielectric film formed on the substrate can be hydrophobized.

In a method disclosed in Patent Document 2, first, a heater is turned on to introduce 1,3,5,7-tetramethylcyclotetrasiloxane (TMCTS) into a single chemical vapor deposition (CVD) apparatus. Subsequently, without application of a high-frequency voltage, a heat treatment is performed to modify a porous dielectric film such as porous silica. Subsequently, the heater is turned on to introduce TMCTS into the same CVD apparatus, and plasma of the TMCTS is generated through application of a high-frequency voltage. In this way, an dielectric film having high density and hardness can be formed on a low dielectric constant film.

In a method disclosed in Patent Document 3, an organosilicate glass dielectric film which has been subjected to an etching or ashing treatment is placed in contact with a toughening agent composition in a state selected from the group consisting of liquid, vapor, gas, and plasma to thereby perform an annealing treatment. In this way, it is possible to prevent undesirable voids from being formed inside a dielectric material between vias and trenches.

In a method disclosed in Patent Document 4, the inner pressure of a chamber is decreased (for example, to a vacuum of 30 kPa or lower) before introducing vapor of hydrophobic compounds into the processing chamber. After that, the vapor of the hydrophobic compounds is introduced to perform a polymerization with a porous dielectric film while maintaining the reduced pressure. In this way, the dispersibility of the hydrophobic compounds within the chamber is improved, and the concentration of the compounds in the pores becomes uniform.

In the method disclosed in Patent Document 4, after a porous silica dielectric film is obtained, the inner pressure of a vertical curing furnace is reduced to 400 Pa or lower while maintaining the vertical curing furnace at 400° C. Subsequently, the vapor of TMCTS is introduced into the furnace as a mixed gas together with nitrogen gas to fire for 30 minutes while maintaining the pressure of 500 Pa, and then, the inner pressure of the furnace is risen to 8 kPa to fire for 60 minutes. In this case, the mixed gas of TMCTS and nitrogen gas is always passed through the furnace during the curing so that the mixed gas does not remain in the furnace. A modified porous silica film obtained in this way has pores of which the inner walls are covered with a thin hydrophobic polymerized film.

### RELATED DOCUMENTS

### Patent Documents

[Patent Document 1] Japanese Laid-Open Patent Publication No. 2002-33314
[Patent Document 2] Japanese Laid-Open Patent Publication No. 2005-166716
[Patent Document 3] Japanese Translation of PCT international Application Publication No. 2007-508691
[Patent Document 4] WO2006/088036

### DISCLOSURE OF THE INVENTION

The silylation gas annealing treatment technique of the related art has room for improvement from the perspective that the reduction in dielectric constant and the improvement in insulating properties of the porous dielectric film are not sufficient. For example, in the processes of producing circuit devices, there is a possibility that polar materials such as water will be adsorbed onto the surfaces of micropores so that the low dielectric properties and insulating properties of the porous dielectric film are impaired. As a result, the dielectric constant increases, and inter-electrode insulating properties decreases, thereby deteriorating the performance of circuit devices. If the porous dielectric film absorbs moisture during the use of the circuit devices, there is a possibility that the reliability of the circuit devices can be deteriorated.

However, in the technique of Patent Document 1, in the gas annealing process, the porous dielectric film is exposed to an inert gas atmosphere or an oxidizing environment including reactive oxygen species. If the porous dielectric film which is constructed by the bond of silicon atoms and oxygen atoms is exposed to an oxidizing environment, the terminals of the silicon-oxygen bond are substituted with a hydrophilic group. Thus, hydrophobization is not sufficiently realized.

In the technique of Patent Document 2, TMCTS is introduced, and a heat treatment is performed without application of a high-frequency voltage to modify the porous dielectric film. However, although micropores of the porous dielectric film have a small diameter, the TMCTS molecules have great steric hindrance and include a large number of terminal groups which are likely to polymerize with the terminal groups on the micropore surfaces. Thus, the diffusion speed in the micropores is low, and when a polymerization occurs on the surface layer of the porous dielectric film, it becomes more difficult for the molecules to diffuse into the micropores. Thus, it is not possible to perform a hydrophobic treatment sufficiently.

In the technique of Patent Document 2, after TMCTS is introduced, a reaction is performed with plasma energy through application of a high-frequency voltage. Since the plasma energy is enormous, the energy is likely to cause damage by destroying the terminal groups of the porous dielectric film structure or the micropore surfaces to make the porous dielectric film hydrophilic. Thus, the porous dielectric film may absorb moisture during the manufacturing processes or the use of circuit devices, thereby causing the performance or the reliability of the circuit devices to deteriorate.

In the technique of Patent Document 3, since the toughening agent composition is placed in contact with the surface of the porous dielectric film in a state selected from the group consisting of liquid, vapor, gas, and plasma, the same problems as the techniques of Patent Documents 1 and 2 can occur.

As above, in the techniques of the related art, it is not possible to sufficiently hydrophobize the porous dielectric film.

According to an aspect of the invention, there is provided a method of manufacturing a semiconductor device, comprising:

forming a porous dielectric film on a substrate;

disposing the substrate having the porous dielectric film formed thereon inside a chamber;

introducing siloxane into the chamber in which the substrate is disposed and heating the substrate to a first temperature; and

heating the substrate to which the introduced siloxane adheres to a second temperature higher than the first temperature,

wherein in the heating to the first temperature, a pressure inside the chamber is maintained to be equal to or lower than 1 kPa, and

wherein the first temperature is equal to or higher than a temperature at which the pressure inside the chamber is a saturated vapor pressure of the siloxane, and is equal to or lower than a temperature at which a polymerization between the porous dielectric film and the siloxane starts.

According to the aspect of the invention, a siloxane is introduced into a chamber having a substrate disposed therein, the pressure inside the chamber is maintained to be equal to or lower than 1 kPa, and the temperature is heated to a temperature at which the pressure inside the chamber is equal to or higher than a saturated vapor pressure of the siloxane and is equal to or lower than a temperature at which the polymerization between the porous dielectric film and the siloxane start. In this way, the siloxane can adhere to and penetrate into the porous dielectric film. Subsequently, by heating the substrate further, it is possible to perform the polymerization between the porous dielectric film and the siloxane. Thus, hydrophobic properties can be imparted micropores of the porous dielectric film with and absorption of moisture can be suppressed during the manufacturing processes or the use of circuit devices.

According to the invention, contamination and absorption of moisture can be suppressed on the surface of the porous dielectric film while the reaction between the porous dielectric film and the siloxane efficiently is performed. Therefore, low dielectric properties of the porous dielectric film can be further secured and insulating properties durable for practical use can be obtained.

### BRIEF DESCRIPTION OF THE DRAWINGS

The above-described objects and the other objects, features, and advantages will become more obvious from the following preferred embodiments and the accompanying drawings, in which:

FIG. 1 is a flowchart illustrating a method of manufacturing a semiconductor device according to a first embodiment;

FIG. 2 is a diagram illustrating an apparatus used in the method of manufacturing the semiconductor device according to the first embodiment; and

FIG. 3 is a diagram illustrating a method of manufacturing a semiconductor device according to a second embodiment.

### DESCRIPTION OF EMBODIMENTS

Hereinafter, embodiments of the invention will be described with reference to the drawings. Throughout the drawings, the same constituent elements will be denoted by the same reference numerals, and redundant description thereof is not provided.

### First Embodiment

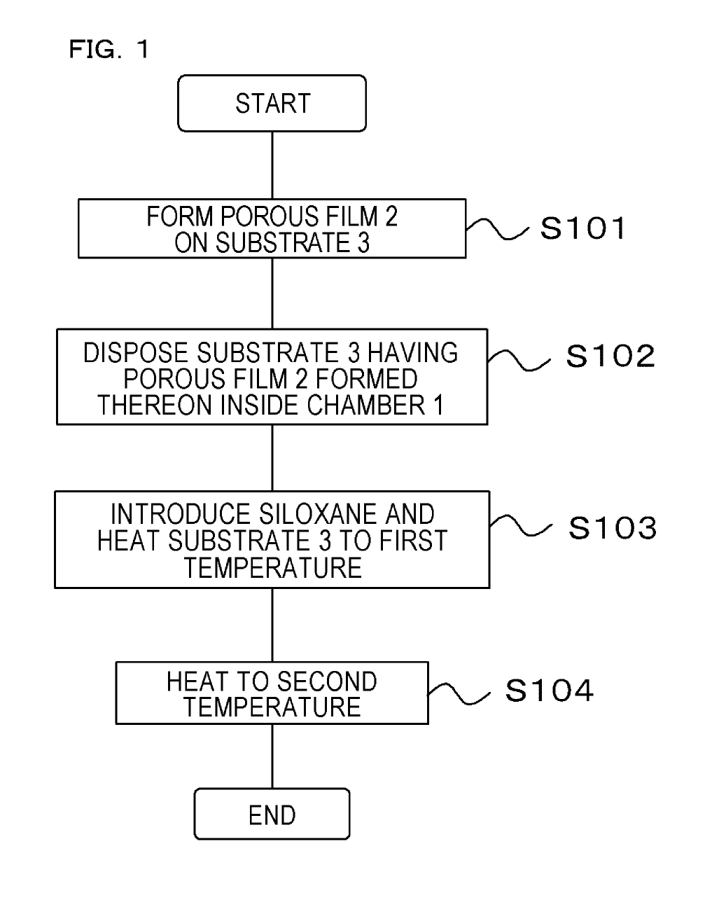

FIG. 1 is a diagram illustrating a manufacturing method according to the present embodiment. The method of the present embodiment includes: a step (S101) of forming a porous dielectric film 2 on a substrate 3; a step (S102) of disposing the substrate 3 having the porous dielectric film 2 formed thereon inside a chamber 1; a step (S103) of introducing siloxane into the chamber 1 in which the substrate 3 is disposed and heating the substrate 3 to a first temperature; and a step (S104) of heating the substrate 3 to which the introduced siloxane adheres to a second temperature higher than the first temperature. In S103, a pressure inside the chamber 1 is maintained to be equal to or lower than 1 kPa. In the present embodiment, the first temperature is equal to or higher than the temperature at which the pressure inside the chamber 1 is a saturated vapor pressure of the siloxane, and is equal to or lower than the temperature at which a polymerization between the porous dielectric film 2 and the siloxane starts.

Each of the steps of the present embodiment will be described in more detail.

### [S101: Step of Forming the Porous Dielectric Film 2 on the Substrate 3]

A mixed solution of an organosiloxane and a surfactant is coated on the substrate 3 by a spin coating method to form a coated film. Any substrate which is typically used can be used as the substrate 3. Examples thereof include substrates formed of glass, quartz, silicon wafer, and stainless steel. Subsequently, the substrate 3 is heated in a nitrogen gas atmosphere to polymerize the organosiloxane. In this case, the surfactant is agglutinated and then gasified. In this way, the porous dielectric film 2 is formed on the substrate 3. Here, if the surfactant is not sufficiently desorbed, an ultraviolet irradiation treatment may be performed in a reduced pressure atmosphere or a nitrogen atmosphere.

### [S102: Step of Disposing the Substrate 3 in the Chamber 1]

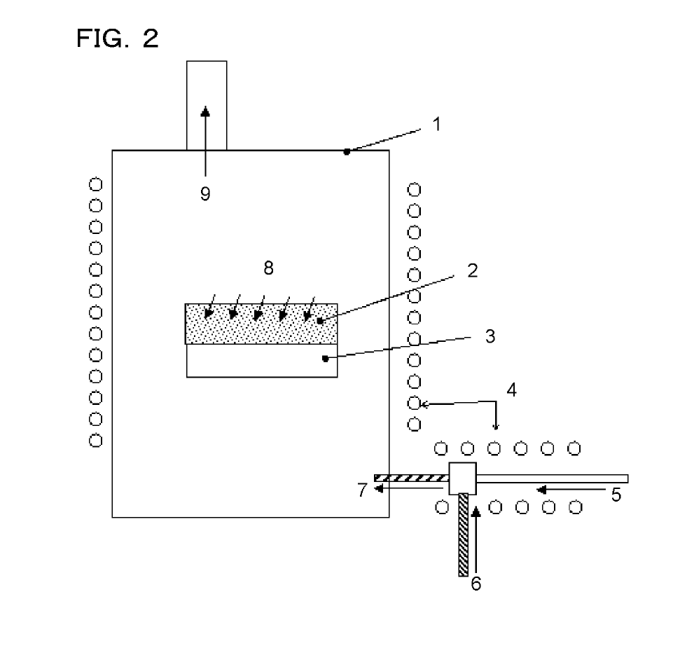

Immediately after the porous dielectric film 2 is formed in S101, the substrate 3 is disposed in the chamber (quartz-vacuum chamber) 1. FIG. 2 is a diagram showing the structure of the chamber 1.

### [S103: Step of Heating the Substrate 3 to the First Temperature]

After the substrate 3 is disposed in the chamber 1 in S102, the pressure inside the chamber 1 is reduced to 1 kPa or lower. Although the lower-limit pressure is not particularly limited, the pressure is preferably equal to or higher than 1×10⁻³ kPa, and is equal to or higher than 0.1 kPa when practicality is taken into consideration.

Subsequently, gas containing siloxane is introduced into the chamber 1. As the siloxane, cyclic siloxane compounds can be used, for example. As the cyclic siloxane compounds, compounds represented by general formula (1) can be used.

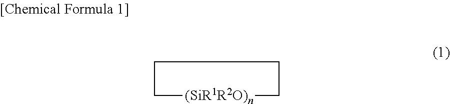

In the formula, R¹ and R² may be the same or different from each other and each represent H, C₆H₁₅, CₐH₂ₐ₊₁, or CF₃(CF₂)_{b}(CH₂)_{c} and a halogen atom, and a is an integer of 1 to 3, b is an integer of 0 to 10, c is an integer of 0 to 4, and n is an integer of 3 to 8. The cyclic siloxane compounds represented by the above formula preferably have at least two Si—H bonds, and at least one of R¹ and R² is preferably H.

Specific examples of the cyclic siloxane compounds include tri (3,3,3-trifluoropropyl)trimethylcyclotrisiloxane, triphenyltrimethylcyclotrisiloxane, 1,3,5,7-tetramethylcyclotetrasiloxane, octamethylcyclotetrasiloxane, 1,3,5,7-tetramethyl-1,3,5,7-tetraphenylcyclotetrasiloxane, tetraethylcyclotetrasiloxane, and pentamethylcyclopentasiloxane. Among these cyclic siloxane compounds, 1,3,5,7-tetramethylcyclotetrasiloxane (TMCTS) is preferable. The cyclic siloxane compounds used in the present embodiment may be used singly or in any combination of at least two of them.

When the siloxane 6 is a gas, a gas 7 containing the siloxane can be introduced into the chamber 1 together with an inert gas (for example, nitrogen, argon, and the like). When the siloxane is a liquid, a liquid siloxane 6 is blown into an inert gas 5 which is heated to a temperature equal to or higher than the boiling point of the siloxane, so that the siloxane can be gasified. When the siloxane is a solid, a solid siloxane is melted by heating, and the melted siloxane 6 is blown into an inert gas which is heated to a temperature equal to or higher than the boiling point of the siloxane, so that the melted siloxane can be gasified. In this way, the gas 7 containing the siloxane can be introduced into the chamber 1.

Additives having the effect of inhibiting a radical reaction may be added to the gas 7 containing the siloxane. Examples of such additives include phenolic compounds, unsaturated hydrocarbons, and preferably, phenols, hydroquinones, or mixtures thereof can be used. These additives can be mixed into the inert gas 5 by the same method as the siloxane 6.

In S103, the chamber 1 is heated by a coil heater 4 while introducing the gas 7 containing the siloxane into the chamber 1 in the above-described manner. In this way, the substrate 3 is heated to a first temperature. The first temperature may be set to a temperature at which the siloxane can be present as a gas in the chamber 1, and is preferably set to a temperature at which the siloxane can efficiently adhere to and penetrate into the porous dielectric film 2. In FIG. 2, diffusion of siloxane vapor is depicted by reference numeral 8.

As described above, the first temperature is equal to or higher than a temperature at which the pressure inside the chamber 1 is a saturated vapor pressure of the siloxane and is equal to or lower than a temperature at which a polymerization between the porous dielectric film 2 and the siloxane starts. The first temperature can be equal to or higher than the boiling temperature of the siloxane at 100 kPa (760 Torr). For example, when cyclic siloxane compounds are used, the first temperature is preferably equal to or higher than 100° C. Preferably, the first temperature is set to 134° C. or higher when TMCTS or hexamethylcyclotrisiloxane is used as the cyclic siloxane compounds, 175° C. or higher when octamethylcyclotetrasiloxane is used, and 210° C. or higher when decamethylcyclotetrasiloxane is used.

In S103, the substrate 3 may be exposed to the gas 7 containing the siloxane for a predetermined period while heating the substrate 3 to the first temperature. The predetermined period is preferably set to a period range in which the siloxane can adhere to and penetrate into the substrate 3, and in which the throughput of the manufacturing processes does not deteriorated. Specifically, the predetermined period is 1 second or longer, more preferably 2 seconds to 30 minutes, and even more preferably about 10 minutes. The pressure inside the chamber 1 is maintained to be equal to or lower than 1 kPa by performing regulations of the evacuation rate of a vacuum pump, or the like. In FIG. 2, pump evacuation is denoted by reference numeral 9.

### [S104: Step of Heating the Substrate 3 to the Second Temperature]

Subsequently, the temperature inside the chamber 1 is risen to heat the substrate 3 to the second temperature. The second temperature is equal to or higher than a temperature at which a polymerization between the porous dielectric film 2 and the siloxane starts. In this way, the polymerization between the porous dielectric film 2 and the siloxane which has adhered to and penetrated into the substrate 3 occurs. Specifically, the second temperature is preferably 250° C. to 600° C. from the perspective that a sufficient reaction rate can be obtained, and that the methyl group of the siloxane is hardly desorbed by heat. The second temperature is more preferably 350° C. to 450° C. from the perspective that deterioration in the reliability of semiconductor integrated circuit devices can be prevented more efficiently. The predetermined period may be set so as to perform the polymerization of the siloxane sufficiently, and preferably is 1 minute to 100 minutes. The polymerization proceeds more efficiently when heating the substrate while supplying the gas 7 containing the siloxane. In this case, the pressure inside the chamber 1 is also maintained to be equal to or lower than 1 kPa by regulations of the evacuation rate of a vacuum pump, or the like. In this way, the surfaces of the porous dielectric film 2 are hydrophobized.

Subsequently, the gas 7 containing the siloxane is discharged from the chamber 1, and only nitrogen gas 5 is filled into the chamber 4. The substrate 3 is cooled down to room temperature (25° C.) and taken out of the chamber 1.

Next, the operation and effect of the present embodiment will be described. According to the method of the present embodiment, the gas 7 containing the siloxane is introduced into the chamber 1 in which the substrate 3 is disposed, the pressure inside the chamber 1 is maintained to be equal to or lower than 1 kPa, and the substrate 3 is heated to be equal to or higher than a temperature at which the pressure inside the chamber 1 is the saturated vapor pressure of the siloxane and to be equal to or lower than a temperature at which a polymerization between the porous dielectric film 2 and the siloxane starts. In this way, the siloxane can adhere to and penetrate into the porous dielectric film 2. Subsequently, when the substrate 3 is heated, the polymerization between the porous dielectric film 2 and the siloxane is performed. Thus, hydrophobic properties can be imparted to the micropores of the porous dielectric film 2, and absorption of moisture can be suppressed during the manufacturing processes or the use of circuit devices.

According to the findings of the present inventors, at the temperature (polymerization temperature) at which the siloxane and the porous dielectric film can be polymerized, there is a tradeoff relationship between the efficiency in the hydrophobic treatment on the surfaces of the porous dielectric film and the contamination of impurities into the porous dielectric film. Siloxane molecules can polymerize with each other as well as with the porous dielectric film. Thus, products obtained through the polymerization between siloxane molecules adhere onto the surfaces of the porous dielectric film and the inner surfaces of the chamber as particles, thus contaminating the porous dielectric film. When the low-pressure treatment is performed in a state where the substrate is heated to the polymerization temperature, the efficiency of the polymerization decreases although the generation of particles can be suppressed. On the other hand, when the high-pressure treatment is performed, the amount of particles generated increases.

In the technique of Patent Document 4, the siloxane is introduced into the chamber at the polymerization temperature (400° C.) Thus, even if the pressure is controlled, there is room for improvement from the viewpoint of balance between the efficiency of the hydrophobic treatment and a reduction of particles.

On the other hand, according to the method of the present embodiment, the siloxane is introduced into the chamber 1 in which the substrate 3 is disposed, the pressure inside the chamber 1 is maintained to be equal to or lower than 1 kPa, and the substrate 3 is heated to equal to or higher than a temperature at which the pressure inside the chamber 1 is the saturated vapor pressure of the siloxane and to equal to or lower than a temperature at which a polymerization between the porous dielectric film 2 and the siloxane starts. In this way, the siloxane can adhere to the porous dielectric film 2 while the polymerization between the porous dielectric film 2 and the siloxane is suppressed. Subsequently, when the substrate 3 is heated, the polymerization reaction between the porous dielectric film 2 and the siloxane occurs, and the porous dielectric film 2 can be hydrophobized. In this case, the siloxanes inside the chamber 1 might be polymerized to generate particles. However, since the siloxane has adhered to the surfaces of the porous dielectric film 2, contamination is suppressed on the surfaces of the porous dielectric film 2. Thus, the porous dielectric film 2 and the siloxane efficiently can be hydrophobized, and the contamination can be suppressed on the surfaces of the porous dielectric film 2.

On the other hand, in the present embodiment, the temperature (first temperature) when introducing the siloxane is maintained to be a relatively low temperature which is equal to or higher than a temperature at which the temperature inside the chamber is the saturated vapor pressure of the siloxane and which is equal to or lower than a temperature at which a polymerization between the porous dielectric film 2 and the siloxane starts. As a result, the dielectric constant of the porous dielectric film 2 can be smaller than that of in the related art, and favorable insulating properties can be available. The reason is that the siloxane can diffuse into the porous dielectric film 2 when the substrate 3 is heated to the first temperature. In this way, most surfaces of the micropores can be silylated with the siloxane at the second temperature. Thus, the micropore surfaces are hydrophobized, and adsorption of moisture can be suppressed in the micropores and an increase in the dielectric constant and a decrease in the insulating properties can be suppressed. Accordingly, intended low dielectric properties can be secured on the porous dielectric film 2, and insulating properties are available for withstanding practical use.

### Second Embodiment

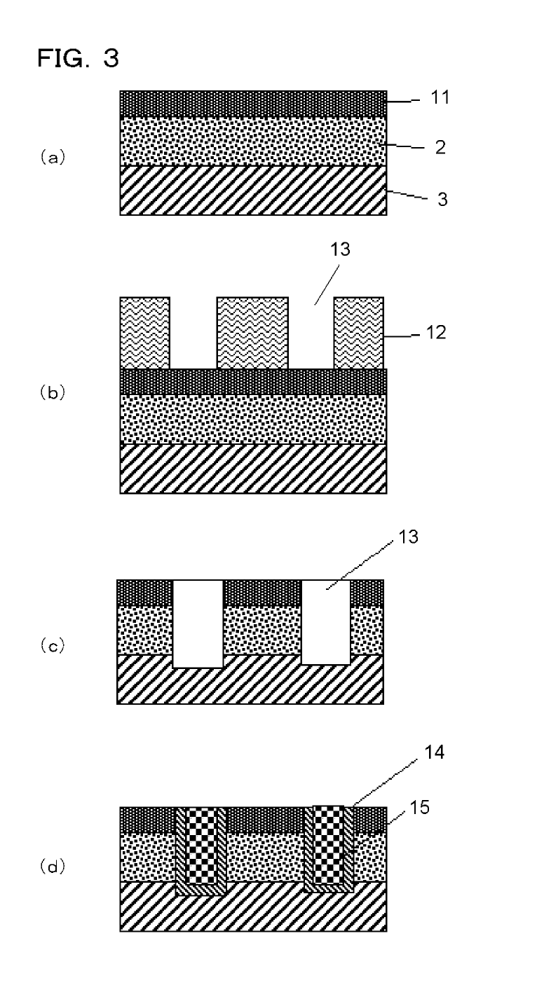

The second embodiment is different from the first embodiment in that a copper interconnect is formed on the porous dielectric film. In FIG. 3(c), the processes of S102 to S104 shown in FIG. 1 are executed.

A laminated film in which a porous dielectric film 2 and a non-porous dielectric film 11 are sequentially laminated is formed on a substrate 3 (see FIG. 3(a)). Although not shown, a interconnect layer may be formed between the substrate 3 and the porous dielectric film 2. Subsequently, a photoresist 12 is formed on the substrate 3, and an etching mask is formed by photolithography. The porous dielectric film is subjected to plasma etching using a fluoride gas to form an etching pattern 13 (see FIG. 3(b)).

The photoresist 12 is removed by oxygen plasma (see FIG. 3(c)). Here, the pore width of the porous dielectric film 2 can be checked by observing with an electron microscope.

Subsequently, the same processes as those of S103 and S104 of the first embodiment are performed to hydrophobize the surfaces of the porous dielectric film 2.

Subsequently, a tantalum film 14 is formed by a sputtering method, and a copper film 15 is embedded into the etching pattern 13 by a sputtering method. Subsequently, copper and tantalum on the surfaces of the substrate 3 are removed by a chemical mechanical polishing (CMP) method, whereby a copper interconnect is formed in the porous dielectric film 2 and the non-porous dielectric film 11 (see FIG. 3(d)).

Next, the operation and effect of the present embodiment will be described. Unlike the first embodiment, in the present embodiment, the exposed area on the surfaces of the porous dielectric film 2 is only the side walls of the etching pattern 13. Therefore, the exposed area of the porous dielectric film 2, which is exposed to the siloxane-containing gas, is local. However, the method of the present embodiment can be applied to a structure in which this kind of siloxane is not easily diffused.

While embodiments of the invention have been described with reference to the drawings, these embodiments are examples of the invention, and various other configurations can be adopted.

### EXAMPLE

### Example 1

A hydrophobic treatment on the porous dielectric film 2 was performed inside the chamber 1 shown in FIG. 2 in accordance with the flow shown in FIG. 1. A mixed solution (coating solution: ULKS (registered trademark) from ULVAC INC.) including surfactant and organosiloxane was coated onto the substrate 3 by a spin coating method, and the substrate 3 was heated to 350° C. in a nitrogen gas atmosphere to obtain a porous dielectric film 2. The porous dielectric film 2 had a pore diameter of about 3 nm when analyzed with a small-angle X-ray scattering method. Immediately after that, the substrate 3 was loaded into the chamber 1, the pressure inside the chamber 1 was reduced to 1 kPa or lower, and the chamber 1 was heated to 200° C. by a coil heater. Subsequently, liquid TMCTS 6 was gasified by blowing it into the stream of nitrogen gas 5 heated to 150° C., and the gas 7 containing TMCTS was introduced into the chamber 1. Subsequently, the substrate 3 was maintained at 200° C., and the pressure inside the chamber 1 was maintained at 1 kPa for 10 minutes while regulating the evacuation rate of a vacuum pump. After that, the temperature inside the chamber 1 was gradually increased to 350° C., and the substrate 3 was exposed to the gas 7 containing TMCTS for 60 minutes while maintaining the pressure inside the chamber 1 at 1 kPa.

Subsequently, after the gas 7 containing TMCTS was discharged from the chamber 1, nitrogen gas was filled into the chamber 1. The temperature of the substrate 3 was decreased to room temperature (25° C.), and the substrate 3 was taken out of the chamber 1. The dielectric constant and a leakage current of the porous dielectric film 2 on the substrate 3 were measured by a mercury probe method.

### Comparative Example 1

In S103 and S104, the same processes as those of Example 1 were performed without introducing the gas 7 containing TMCTS into the chamber 1.

As a result, the dielectric constant of the hydrophobized porous dielectric film 2 obtained by the Example was about 2.0. The leakage current was 3×10⁻⁹ A/cm² or lower under an electric field intensity of 1 MV/cm and was negligibly small. On the other hand, the dielectric constant of the substrate 3 of the Comparative Example was about 4.0. The results of the Comparative Example are considered that the substrate adsorbed moisture in the air when it was taken out of the chamber 1 so that the dielectric constant increased to 3.0 or higher, and that the dielectric constant was not decreased despite the porous properties.

### Example 2

A copper interconnect was formed on a porous dielectric film in accordance with the method shown in FIG. 3. In FIG. 3(c), the processes of S102 to S104 shown in FIG. 1 were executed, and a hydrophobic treatment on the porous dielectric film 2 was performed inside the chamber 1 shown in FIG. 2. First, a laminated film of a non-porous dielectric film 11 and the porous dielectric film 2 was formed on the substrate 3. Subsequently, an etching mask was formed by photolithography, the porous dielectric film 2 was subjected to plasma etching using a fluoride gas, and then the photoresist 12 was removed by oxygen plasma. When the porous dielectric film 2 was observed with an electron microscope, a trench having a width of 100 nm, which was formed thereon, was observed. After that, the substrate 3 was loaded into the chamber 1, and the pressure inside the chamber 1 was vacuumed to 1 kPa or lower. The chamber 1 was heated to 200° C. by a coil heater, and the gas 7 containing TMCTS was introduced into the chamber 1. Introduction of the gas 7 containing TMCTS was carried out by blowing a TMCTS solution supplied in a liquid form into nitrogen gas 5 heated to 150° C. and gasifying the TMCTS. In a state where the substrate 3 was maintained at 200° C., the pressure inside the chamber 1 was maintained at 1 kPa for 10 minutes by regulating the evacuation rate of a vacuum pump. After that, the temperature of the chamber 1 was gradually increased to 350° C., and the substrate 3 was exposed to vapor for 60 minutes while maintaining the pressure inside the chamber 1 at 1 kPa.

Subsequently, after the gas inside the chamber 1 was discharged, nitrogen gas 5 was filled into the chamber 1. The temperature of the substrate 3 was decreased to room temperature (25° C.), and the substrate 3 was taken out of the chamber 1. The tantalum film 14 was formed to a thickness of 15 nm by a sputtering method, and the copper film 15 was embedded into the etching pattern 13 to a thickness of 50 nm by a sputtering method. Furthermore, the copper film 15 was further formed to a thickness of 500 nm by electroplating of copper. Subsequently, the copper and tantalum on the surfaces of the substrate 3 were removed by a CMP method. In this way, the copper interconnect was formed in the porous dielectric film 2 and the non-porous dielectric film 11. The electrostatic capacitance between the facing interconnect s and a leakage current were measured by an automatic probing station.

### Comparative Example 2

In S103 and S104, the same processes as those of Example 2 were performed without introducing the gas 7 containing TMCTS into the chamber 1.

As a result, in Example 2, the electrostatic capacitance and the leakage current were smaller than those of Comparative Example 2. This is considered that the substrate that was not exposed to the siloxane vapor adsorbed moisture in the air during the period between the forming of the etching pattern 14 and the forming of the tantalum film 14, so that the dielectric constant increased, and that the dielectric constant was not decreased despite the porous properties.

This application is based upon and claims the benefit of priority from Japanese Patent Application No. 2009-72401 filed on Mar. 24, 2009, the entire contents of which are incorporated herein by reference.

1. A method of manufacturing a semiconductor device, comprising:
forming a porous dielectric film on a substrate;
disposing the substrate having the porous dielectric film formed thereon inside a chamber;
introducing siloxane into the chamber in which the substrate is disposed and heating the substrate to a first temperature; and
heating the substrate to which the introduced siloxane adheres to a second temperature higher than the first temperature,
wherein in the heating to the first temperature, a pressure inside the chamber is maintained to be equal to or lower than 1 kPa, and
wherein the first temperature is equal to or higher than a temperature at which the pressure inside the chamber is a saturated vapor pressure of the siloxane, and is equal to or lower than a temperature at which a polymerization between the porous dielectric film and the siloxane starts.

2. The method of manufacturing the semiconductor device according to claim 1,
wherein the second temperature is equal to or higher than the temperature at which the polymerization between the porous dielectric film and the siloxane starts.

3. The method of manufacturing the semiconductor device according to claim 1,
wherein the first temperature is equal to or higher than 100° C.

4. The method of manufacturing the semiconductor device according to claim 1,
wherein the siloxane is 1,3,5,7-tetramethylcyclotetrasiloxane.

5. The method of manufacturing the semiconductor device according to claim 2,
wherein the first temperature is equal to or higher than 100° C.

6. The method of manufacturing the semiconductor device according to claim 2,
wherein the siloxane is 1,3,5,7-tetramethylcyclotetrasiloxane.

7. The method of manufacturing the semiconductor device according to claim 3,
wherein the siloxane is 1,3,5,7-tetramethylcyclotetrasiloxane.
